(19) United States
(12) Patent Application Publication
(10) Pub. No.: US 2026/0180233 A1
(43) Pub. Date: Jun. 25, 2026

(54) POWER UNIT FOR A TOOL DEVICE

(71) Applicant: Black & Decker Inc., New Britain, CT (US)

(72) Inventors: Robert Miebach, Idstein (DE); Manfred Droste, Idstein (DE); Benjamin Schramm, Idstein (DE); Thomas Heilig, Idstein (DE); James Standaloft, Gateshead (GB); Isabell Oeffner, Idstein (DE)

(21) Appl. No.: 19/539,246

(22) Filed: Feb. 13, 2026

Related U.S. Application Data
(63) Continuation of application No. PCT/EP2023/072679, filed on Aug. 17, 2023.

(51) Int. Cl. H01R 13/506; H01M 10/42; H01M 50/213; H01M 50/247; H05K 7/20

(52) U.S. Cl. CPC H01R 13/506; H01M 10/425; H01M 50/213; H01M 50/247; H05K 7/20254

(57) ABSTRACT

The invention relates to a power unit for a tool comprising at least one electrical component. The power unit includes a housing configured to removably receive at least one battery pack, an electrical connector coupled to the housing and configured to electrically connect to at least one electrical component, and a frame coupled to the housing. The frame projects beyond the housing and the electrical connector to protect the housing and the electrical connector from impact.

### CROSS-REFERENCE TO RELATED APPLICATION

The present application is a continuation of International Patent Application No. PCT/EP2023/072679, filed on Aug. 17, 2023, entitled POWER UNIT FOR A TOOL DEVICE, and claims the benefit of priority thereof under 35 U.S.C. § 120.

### INCORPORATION BY REFERENCE

The disclosure of International Patent Application No. PCT/EP2023/072679, filed on Aug. 17, 2023, entitled POWER UNIT FOR A TOOL DEVICE, is hereby incorporated by reference for all purposes as if set forth in its entirety.

### FIELD

The technology relates to the field of power units for tools, specifically focusing on the design and construction of power units that provide electrical power to various electrical components in tools.

### BACKGROUND

Ground mounted power packs are widely used in various industries to provide portable power to a range of tools and equipment. These power packs typically include mains power electrical connection and an electrical connector for connecting to the tool or equipment. The housing is often mounted on a frame, which provides support and protection for the power pack during use.

In many work environments, such as construction sites, it is necessary to move the power pack around the worksite as work progresses. However, existing designs of ground mounted power packs can be difficult to transport and manoeuvre due to their size, weight, and shape. Additionally, the frames of these power packs often have sharp edges, which can cause problems when moving the power pack around a worksite.

One issue with the sharp edges of existing power pack frames is that they can get caught between rebars or other obstacles on the worksite. This can create obstructions for users, who must then stop their work to free the power pack before they can continue. This interruption in work can lead to lost time and reduced productivity, which is undesirable.

Another issue with the sharp edges of existing power pack frames is that they can cause damage to the power pack itself. For example, if the frame gets caught between rebars and the user attempts to force the power pack free, the sharp edges may dig into the housing or other components of the power pack. This can result in damage to the power pack, which may require costly repairs or even replacement of the entire unit.

In many work environments, such as concrete job sites, the conditions can be harsh and demanding, leading to wear and tear on the power tool components. One issue faced in these environments is the short lifespan of the silicone cap that covers the rocker switch. The silicone cap is designed to protect the switch from debris and dust, but it often wears out quickly, requiring frequent replacement. This can be both time-consuming and costly for users.

Another problem associated with the rocker switch is the difficulty in operating it while wearing gloves. In many job sites, gloves are necessary for safety reasons, but they can make it challenging to effectively operate the rocker switch. This can affect the efficiency and ease of use of the power tool, leading to decreased productivity.

Additionally, users often struggle to feel the different positions of the rocker switch, making it impractical for switches with more than two positions. This lack of tactile feedback can lead to confusion and uncertainty when trying to determine the current setting of the switch, further impacting the usability of the power tool.

The prior art has attempted to address these issues by using silicone caps to cover the rocker switch, but these caps have proven to be insufficient in providing the necessary durability and protection in harsh work environments.

Power tools and equipment, particularly those used in construction and outdoor environments, often require protection for their electronic components from external elements such as moisture, dust, and debris. This is particularly important for tools that operate in wet conditions or with materials such as wet concrete. To protect the electronic components, the power units of these tools may have a housing design that prevents or limits the ingress of external elements.

However, the design of the power unit housing can lead to cooling problems, especially when the tool operates at high voltages and requires frequent switching for the motor. The lack of air circulation within the housing prevents effective heat dissipation from the electronic components, which can lead to overheating and potential damage to the components. Furthermore, high voltage operation generates more heat within the electronic components, exacerbating the cooling issues caused by the housing design. This can lead to a higher risk of component failure and reduced product lifespan.

### SUMMARY

In a first aspect of the disclosure there is provided power unit for a tool comprising at least one electrical component, the power unit comprising: a housing configured to removably receive at least one battery pack; an electrical connector coupled to the housing and configured to electrically connect the at least one battery pack to at least one electrical component; a frame coupled to the housing, wherein the frame projects beyond the housing and the electrical connector to protect the housing and the electrical connector from impact.

Optionally, the electrical connector is configured to electrically connect to the at least one electrical component with a flexible tool connection comprising at least one electrical wire configured to electrically connect the battery pack and the at least one electrical component.

Optionally, the frame projects beyond the housing and the battery pack when the battery pack is mounted to the housing to protect the battery pack from impact.

Optionally, an outer part of the frame configured to engage the ground is symmetrical about a longitudinal axis of the power unit.

Optionally, the frame comprises a forward frame portion having a forward sloped portion configured to provide a clearance between the forward frame portion and the ground.

Optionally, the forward sloped portion is configured to allow sliding over rebars up to 35 mm in height difference.

Optionally, the forward frame portion is smaller than a rear frame portion.

Optionally, the forward sloped portion of the forward frame portion is configured to surround at least a portion of the electrical connector to provide protection to the electrical connector from impact or damage.

Optionally, the frame is made from one or more of gas injection moulded plastic, injection moulded plastic, reinforced plastic, composite material, fibreglass, and/or carbon fibre.

Optionally, the frame further comprises one or more fastening holes configured to engage with a carry strap clip.

Optionally, the frame further comprises one or more metal inserts arranged to increase the stiffness of the frame.

Optionally, the frame comprises a first frame side and a second frame side, and at least one cross strut connected between the first frame side and the second frame side.

Optionally, the housing, the battery pack, and the electrical connector are contained within a volume bounded by the frame.

Optionally, the frame comprises a first ground contacting rail and a second ground contacting rail are parallel to the ground when contacting the ground.

Optionally, the frame partially surrounds the exterior of the housing such that the housing does not touch the ground when the frame rests on the ground.

Optionally, the at least one electrical component comprises one or more of a motor, switch, circuit board, LED indicator, heating element, sensor, solenoid, transformer, capacitor, resistor, transistor, fuse, relay, microcontroller, power supply, potentiometer, and encoder.

According to a second aspect of the disclosure there is provided a power unit for a tool device comprising at least one electrical component, the power unit comprising: a housing configured to removably receive at least one battery pack; an electrical connector coupled to the housing and configured to electrically connect the at least one battery pack to the at least one electrical component; and a rotary actuator rotatable about a rotary actuator rotation axis between at least a first rotary actuator position and a second rotary actuator position, wherein the first rotary actuator position corresponds to a power OFF mode and the second rotary actuator position corresponds to a first operational mode of the power unit.

Optionally, the electrical connector is configured to electrically connect to the at least one electrical component with a flexible tool connection comprising at least one electrical wire configured to electrically connect the battery pack and the at least one electrical component.

Optionally, the rotary actuator is further rotatable to a third rotary actuator position, wherein the third rotary actuator position corresponds to a second operational mode of the power unit.

Optionally, the first operation mode corresponds to a power ON mode and the second operational mode corresponds to a remote-control mode.

Optionally, the rotary actuator comprises a rotary actuator knob mounted on a first end of a rotary actuator shaft.

Optionally, the rotary actuator knob comprises a tapered finger configured to point to one or more rotary actuator position symbols each corresponding to a rotary actuary position.

Optionally, at least one microswitch is configured to detect the rotary actuator in the second rotary actuator position or the third rotary actuator position and generate a signal corresponding to the detected position.

Optionally, a controller is connected to the at least one microswitch and configured to detect the signal generated by the at least one microswitch and activate the corresponding operational mode of the power unit.

Optionally, the controller is further configured to provide power to the at least one electrical component of the tool device when the rotary actuator is in the second rotary actuator position or the third rotary actuator position.

Optionally, a wireless remote-control module is configured to switch the power supply on and off remotely when the rotary actuator is in the third rotary actuator position (416).

Optionally, the wireless remote-control module is configured to communicate with a remote-control device using one or more of the following wireless protocols Bluetooth, Zigbee, Wi-Fi, Infrared, RF (Radio Frequency), LoRa (Long Range), and/or Cellular network (e.g., 4G, 5G).

Optionally, a remote device pairing button configured to initiate pairing with the remote-control device.

Optionally, the rotary actuator comprises a switch cam mounted on the rotary actuator shaft and configured to engage and actuate the at least one microswitch when the rotary actuator is in the second rotary actuator position or the third rotary actuator position.

Optionally, the switch cam comprises at least one retaining detent configured to positively retain the switch cam and the rotary actuator in the first rotary actuator position, the second rotary actuator position, or the third rotary actuator position.

Optionally, the switch cam comprises a first camming surface configured to engage and move a first lever end of a first microswitch and actuate the first microswitch when the rotary actuator is in the second rotary actuator position, and a second camming surface configured to engage and move a second lever end of a second microswitch and actuate the second microswitch when the rotary actuator is in the third rotary actuator position.

Optionally, the housing comprises an actuator through hole and the rotary actuator covers the actuator through hole to protect internal components from debris and dust.

According to a third aspect of the disclosure there is provided a power unit for a tool comprising at least one electrical component, the power unit comprising: a housing configured to removably receive at least one battery pack; an electrical connector coupled to the housing and configured to electrically connect the at least one battery pack to at least one electrical component; an electronics module mounted within the housing; and a heat sink mounted to the housing and coupled to the electronics module wherein the heat sink comprises an external surface forming part of the exterior of the housing.

Optionally, the electrical connector is configured to electrically connect to the at least one electrical component with a flexible tool connection comprising at least one electrical wire configured to electrically connect the battery pack and the at least one electrical component.

Optionally, the heat sink comprises external radiating ribs projecting from the external surface of the heat sink.

Optionally, the external radiating ribs are spaced at a distance of at least 6 mm from each other.

Optionally, a frame is projecting outward from the housing a greater distance than the external radiating ribs, wherein the frame is configured to protect the external radiating ribs from impact shock.

Optionally, the heat sink further comprises a heat sink wall having an internal surface in contact with the electronics module and configured to transfer heat from the electronics module to the external surface.

Optionally, the electronics module is housed within an internal heat sink volume defined by the heat sink wall.

Optionally, the heat sink is made from one or more of aluminium, copper, steel, titanium, and/or graphite.

Optionally, a thermal paste is applied between the electronics module and the heat sink.

Optionally, a potting boat is configured to receive the electronics module wherein the potting boat is mounted to the heat sink.

Optionally, the housing comprises one or more air holes mounted remote from the heat sink.

Optionally, a heat sink seal is mounted between the housing and the heat sink.

Optionally, the heat sink further comprises at least one air flow channel that are not in fluid communication with the internal heat sink volume.

Optionally, the external radiating ribs comprise rib end chamfers.

Optionally, the rib end chamfers have an incline that matches the incline of a first forward sloped portion and a second forward sloped portion of the frame.

Optionally, the housing does not comprise any air holes configured to provide a direct air flow over the electronics module.

Optionally, the housing does not comprise a fan configured to direct air flow over the electronics module.

### BRIEF DESCRIPTION OF THE DRAWINGS

Examples are described in more detail below with reference to the appended drawings.

FIG. 1 is a perspective view of the power unit for a tool device according to an example;

FIG. 2a is a side view of the power unit for a tool device without a battery pack according to an example;

FIG. 2b is a side view of the power unit for a tool device with a battery pack according to an example;

FIG. 3 is a front view of the power unit for a tool device according to an example;

FIG. 4a is a close-up perspective view of the power unit with a rotary actuator according to an example;

FIG. 4b is a schematic side drawing of the rotary actuator in different positions corresponding to different operational modes of the power unit according to an example;

FIG. 5 is a close-up perspective view with a power unit shown partially in cross-section according to an example;

FIG. 6 is a close-up cross-sectional view of a power unit and a rotary actuator according to an example;

FIG. 7a is a schematic side view of part of a rotary actuator of the power unit according to an example;

FIG. 7b is a close-up perspective view of a rotary actuator of the power unit according to an example;

FIG. 8a is a close-up partial cross-sectional view of a rotary actuator of the power unit according to an example;

FIG. 8b is a cross-sectional view of a rotary actuator of the power unit according to an example;

FIG. 9 is a perspective view with a power unit with a heat sink shown partially in cross-section according to an example; and

FIG. 10 is a close-up side cross-sectional view of a power unit with a heat sink according to an example.

### DETAILED DESCRIPTION

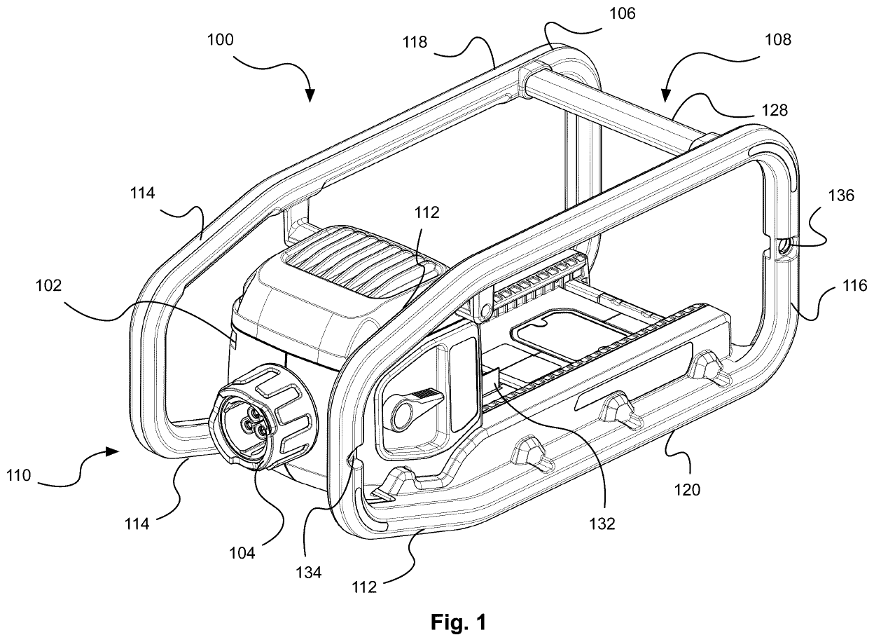

FIG. 1 shows a perspective view of a power unit 100 for a tool device (not shown) according to an example.

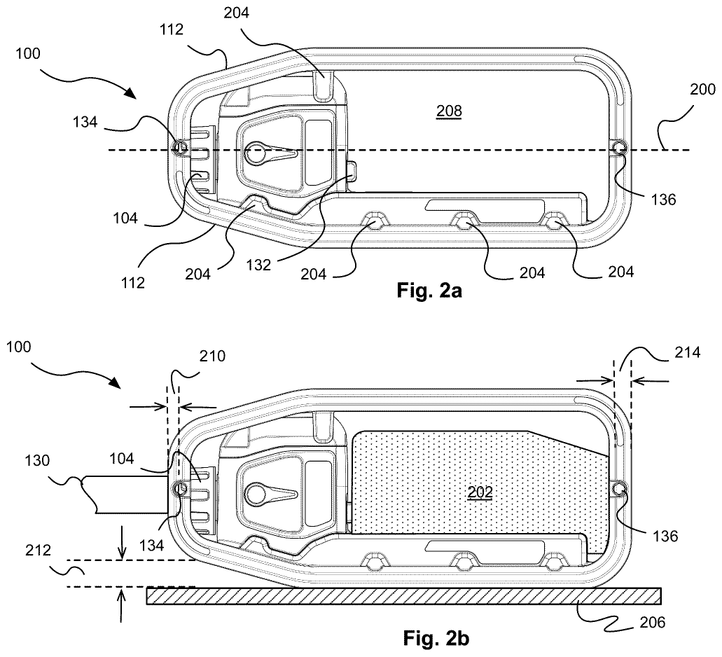

The power source mounted in the power unit 100 can be any suitable power source configured to provide electrical power to the tool device. For example, the power source can be one or more battery packs 202 (best shown in FIG. 2b). Additionally, or alternatively the power source can be a mains power source.

The tool device is connected to the power unit 100 via an electrical hose (not shown). The electrical hose comprises at least one electrical wire and electrically connects a power source (not shown) mounted on the power unit 100 with at least one electrical component in the tool device. The electrical hose is durable and flexible. This means that the tool device can be used remotely from the power unit 100 whilst still being powered from the power source mounted in the power unit 100. The electrical hose in some examples comprises an outer sheath configured to protect the internal electrical wires from caustic or corrosive materials and other mechanical damage.

In some examples, the tool device is a vibrating tool which comprises a motor (not shown) and is configured to drive an oscillating mass (not shown) to cause the tool device to vibrate. The use of a motor operatively connected to an oscillating mass to vibrate the tool device is known and will not be discussed in any further detail.

In use, the user inserts the vibrating tool into a wet concrete mix that has been poured at a worksite. The user grips the electrical hose with one or both hands as required. As the vibrating tool vibrates, the air bubbles in the wet concrete mix rise up in the wet cement mix and are expelled. The vibrating tool is connected via the electrical hose and is remote from the power unit 100.

However, the tool device can be any suitable tool device that is powered by a portable power source e.g., a battery.

The power unit 100 may be utilised in various other tool devices that require electrical power to operate. The tool devices may be handheld or stationary, and may be used in various industries and applications, such as construction, manufacturing, automotive, woodworking, and more.

In one example, the power unit 100 may be used to power a handheld drill or screwdriver. The motor within the tool device may be electrically connected to the power unit 100 via the electrical connector 104, providing the necessary power to drive the drill or screwdriver bit.

In another example, the power unit 100 may be used to power a cutting tool, such as a circular saw, reciprocating saw, or jigsaw. The motor within the cutting tool may be electrically connected to the power unit 100 via the electrical connector 104, providing the necessary power to drive the cutting blade.

In yet another example, the power unit 100 may be used to power a grinding or polishing tool, such as an angle grinder or a rotary tool. The motor within the grinding or polishing tool may be electrically connected to the power unit 100 via the electrical connector 104, providing the necessary power to drive the grinding or polishing attachment.

In some examples, the power unit 100 may also be used to power other types of tool devices, such as sanders, planers, routers, impact wrenches, nail guns, staplers, and more. For example, the tool device can be an inspection light (not shown). Alternatively, the tool device can be a leaf blower or a vacuum cleaner with an integrated motor fan assembly configured to generate an air flow. In some other examples, the tool device can be any electrically powered tool such as a string trimmer, a hedge trimmer, a chain saw, grass shears, hammer, a rammer, a plate compactor etc.

The power unit 100 may be configured to provide the required electrical power and connections for these various tool devices, making it a versatile accessory for a wide range of applications.

Hereinafter, the term “tool device” will be used to describe any suitable tool device or power tool powered by the battery pack 202 mounted on the power unit 100.

In one example, the power unit 100 comprises a housing 102 that is configured to removably receive at least one battery pack 202. The housing 102 is designed to securely hold and connect the battery pack 202, allowing for easy removal and replacement. This feature provides the advantage of enabling users to quickly swap out battery packs 202 when one is depleted, ensuring minimal downtime and increased productivity.

In some examples, the housing 102 includes a battery mounting 132 that is designed to securely hold and connect the battery pack 202. The battery mounting 132 may be configured to electrically and mechanically connect to the battery pack 202, ensuring a stable and reliable connection between the battery pack 202 and the power unit 100. The battery mounting 132 may be connected to the housing 102, providing a convenient location for users to access and replace the battery pack 202.

The mechanical connection of the battery mounting 132 may comprise various mechanisms, such as clips, latches, or other fastening means, that securely hold the battery pack 202 in place within the housing 102. The electrical connection between the battery pack 202 and the housing 102 may comprise various connectors, such as terminals, pins, or other conductive elements, that provide a reliable electrical connection between the battery pack 202 and the power unit 100.

An electrical connector 104 is coupled to the housing 102 and is configured to electrically connect to at least one electrical component. The electrical connector 104 may be connected to a flexible tool connection 130, which contains at least one electrical wire for electrically connecting the battery pack 202 to the at least one electrical component. This ensures that the power unit 100 can efficiently transfer electrical energy from the battery pack 202 to the electrical component, enabling the tool device to function effectively.

The electrical component may be any device or component in the tool device that requires electrical power to operate. In one example, the at least one electrical component may be a motor that converts electrical energy into mechanical energy to drive a tool device. The motor may be an AC motor, a DC motor, a brushless motor, a stepper motor, or any other type of motor suitable for the specific application.

In another example, the electrical component may be a switch that controls the flow of electrical current within the tool device. The switch may be a mechanical switch, an electronic switch, a solid-state switch, a relay, or any other type of switch suitable for the specific application.

In yet another example, the electrical component may be a circuit board that contains various electronic components and connections for controlling the operation of the tool device. The circuit board may include components such as resistors, capacitors, transistors, diodes, inductors, and other electronic components.

In some examples, the power unit 100 may also comprise other electrical components such as LED indicators, heating elements, sensors, solenoids, transformers, capacitors, resistors, transistors, fuses, relays, microcontrollers, power supplies, potentiometers, and encoders. These components may be used to provide additional functionality, control, and feedback for the tool device. In some other examples, the at least one electrical component can be any suitable electrical component in a tool device which is powered by the power unit 100.

The flexible tool connection 130 provides the advantage of allowing the power unit 100 to be easily connected to various tool devices, enabling a wide range of applications and increased versatility for the power unit 100.

The power unit 100 also includes a frame 106 coupled to the housing 102. The frame 106 projects beyond the housing 102 and the electrical connector 104 to protect the housing 102 and the electrical connector 104 from impact. The outer portion of the frame 106 which is configured to engage the ground may be symmetrical about a longitudinal axis 200 of the power unit 100 and may include a rear frame portion 108 and a forward frame portion 110.

In some examples, the forward sloped portion of the forward frame portion 110 is configured to surround at least a portion of the electrical connector 104 to provide protection to the electrical connector 104 from impact or damage. This feature increases the durability and lifespan of the electrical connector 104, ensuring a reliable and efficient connection between the power unit 100 and the at least one electrical component over an extended period of use.

In some examples, the electrical connector 104 may comprise additional features or components to further enhance its durability and reliability. For example, the electrical connector 104 may comprise a locking mechanism (not shown) to securely hold the flexible tool connection 130 in place, preventing it from accidentally becoming disconnected during use. Additionally, the electrical connector 104 may comprise a sealing mechanism (not shown) to protect the electrical connection from moisture, dust, or other contaminants, ensuring that the electrical connection remains secure and reliable even in harsh working environments.

In one example, the design of the frame 106 and material of the power unit 100 play a role in providing protection, durability, and ease of use for the tool device. The frame 106 is designed to be coupled to the housing 102 and to project beyond the housing 102 and the electrical connector 104, protecting these components from impact and damage during use. The frame 106 may also project beyond the battery pack 202 when the battery pack 202 is mounted to the housing 102, providing additional protection to the battery pack 202 from impact.

The frame 106 will now be discussed in more detail with respect to FIGS. 2a and 2b.

FIG. 2a shows a side view of the power unit 100 for a tool device without a battery pack 202 according to an example. The forward frame portion 110 includes a first forward sloped portion 112 configured to provide a clearance between the forward frame portion 110 and the ground 206. The first forward sloped portion 112 may be configured to allow sliding over rebars up to 35 mm in height difference. The forward frame portion 110 may be smaller than the rear frame portion 108. This design allows for a more compact and lightweight power unit 100 while still providing adequate protection for the housing 102, battery pack 202, and electrical connector 104.

The frame 106 may include a first frame side 116 and a second frame side 118, with at least one cross strut 128 connected between the first frame side 116 and the second frame side 118. The frame 106 may also include a first ground contacting rail 120 and a second ground contacting rail 122, which are parallel to the ground 206 when contacting the ground 206.

FIG. 2b shows a side view of the power unit 100 for a tool device with a battery pack 202 according to an example. The frame 106 projects beyond the housing 102 and the battery pack 202 when the battery pack 202 is mounted to the housing 102 to protect the battery pack 202 from impact.

As mentioned above, the outer portion of the frame 106 which is configured to engage the ground is symmetrical about a longitudinal axis 200 of the power unit 100. This symmetrical design allows the frame 106 to contact the ground 206 either way up, providing versatility and ease of use for the tool device. This means that the first forward sloped portion 112 of the forward frame portion 110 provides a forward sloped portion ground clearance 212 irrespective of whether an upper frame portion 124 or a lower frame portion 126 is in contact with the ground 206.

The frame 106 also comprises an upper frame portion 124 and a lower frame portion 126. In use, the lower frame portion 126, or at least part of the lower frame portion 126 is configured to engage the ground 206. The upper frame portion 124 faces upwards away from the ground 206 in normal use. However, as discussed herein, the power unit 100 is symmetrical about the longitudinal axis 200. In this way, the upper frame portion 124 can also engage the ground 206 and the lower frame portion 126 faces away from the ground 206.

In some examples, the rear frame portion 108 and the forward frame portion 110 of the frame 106 are designed to provide different levels of protection and clearance for the power unit 100. The rear frame portion 108 may be larger than the forward frame portion 110, providing additional protection for the housing 102 and battery pack 202 when the power unit 100 is in use. This means that when the user pulls the power unit 100 by the flexible tool connection 130, the user drags the power unit 100 with the forward frame portion 110 moving over obstacles first.

In one example, the forward frame portion 110 is configured to allow sliding over rebars up to 35 mm in height. In some other examples, the forward frame portion 110 is configured to slide over rebars up to 10 mm, 15 mm, 20 mm, 25 mm, 30 mm, 40 mm, 45 mm, 50 mm, 55 mm, 60 mm, 65 mm, 70 mm, 75 mm, 80 mm, 85 mm, 90 mm, 95 mm, or 100 mm. In some other examples, the forward frame portion 110 is configured to slide over rebars up to any required height.

This feature enables the power unit 100 to move smoothly over surfaces with rebars or other obstacles, reducing interruptions and increasing productivity during operation. The clearance provided by the forward frame portion 110 e.g., by the first forward sloped portion 112 and the second forward sloped portion 114 ensures that the power unit 100 can easily navigate over uneven surfaces without getting caught or damaged.

In some examples, the power unit 100 may comprise additional features to further enhance the clearance of the ground 206 and protection of the electrical connector 104. For instance, the frame 106 may include a first forward sloped portion 112 connected to the first ground contacting rail 120 and a second forward sloped portion 114 connected to the second ground contacting rail 122.

The frame 106 may also include a first frame side 116 and a second frame side 118, with at least one cross strut 128 connected between the first frame side 116 and the second frame side 118. The cross struts 128 provide additional structural support and rigidity to the frame 106, further enhancing the protection and durability of the power unit 100.

In some examples, the frame 106 comprises a first ground contacting rail 120 and a second ground contacting rail 122, which are parallel to the ground 206 when contacting the ground 206. The first and second ground contacting rails 120, 122 provide a stable and secure contact with the ground 206, ensuring that the power unit 100 remains stable during use. The cross struts 128 connected between the first frame side 116 and the second frame side 118 provide additional structural support and rigidity to the frame 106, further enhancing the protection and durability of the power unit 100. When the user drags the power unit 100 over the ground 206, the first and second ground contacting rails 120, 122 slide over the ground 206. The first and second ground contacting rails 120, 122 reduce the friction between the power unit 100 and the ground 206 when the user drags the power unit 100 and make the power unit 100 easier to move around a worksite.

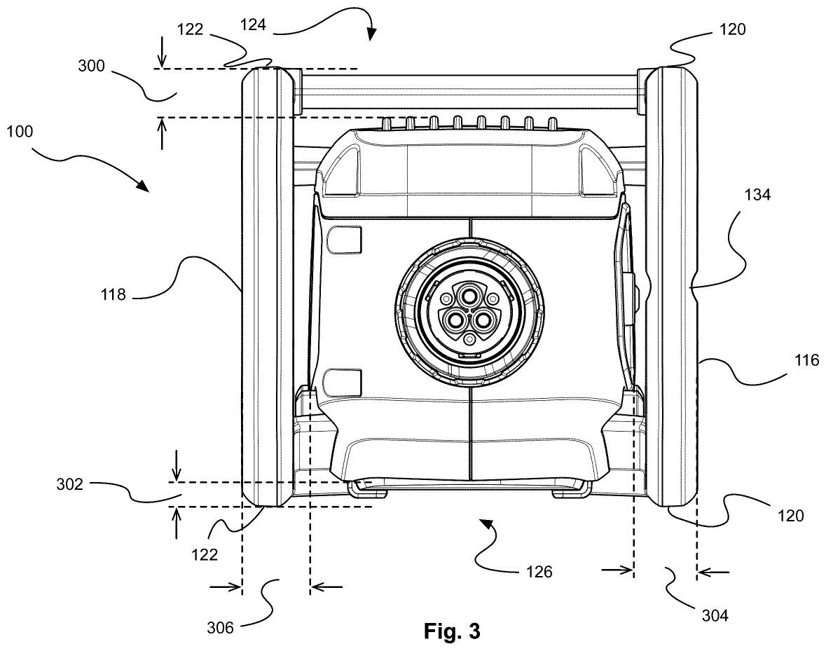

The first ground contacting rail 120 and the second ground contacting rail 122 are better shown side by side in FIG. 3. FIG. 3 shows a front view of the power unit 100 for a tool device according to an example. The forward sloped portion 112 of the forward frame portion 110 is configured to surround at least a portion of the electrical connector 104 to provide protection to the electrical connector 104 from impact or damage.

Since the forward frame portion 110 is configured to surround at least a portion of the electrical connector 104, the electrical connector 104 does not protrude beyond the frame 106 and is not able to snag on other objects or the ground 206 when the power unit 100 is moved by the user. For example, the electrical connector 104 is prevented from digging into the ground 206 if the power unit 100 tips forward onto the forward frame portion 110. Instead, the forward frame portion 110 contacts the ground 206 rather than the electrical connector 104.

In some examples, the frame 106 is made from one or more of gas injection moulded plastic, injection moulded plastic, reinforced plastic, composite material, fibreglass, and/or carbon fibre. These materials provide a lightweight and durable frame 106 that can withstand the rigours of use in various tool devices. The use of plastic and composite materials also allows for elastic deformation of the frame 106, providing better performance during drops and impacts compared to a steel frame.

These materials provide different levels of strength, stiffness, and durability, allowing for a customised frame 106 that meets the specific needs of the tool device and its intended application.

In some examples, the frame 106 may further comprise one or more metal inserts arranged to increase the stiffness of the frame 106. These metal inserts, such as steel inserts in corners, provide defined stiffness in specific regions of the frame 106, enhancing the overall structural integrity and durability of the power unit 100. The use of metal inserts in combination with plastic and composite materials allows for a lightweight yet robust frame 106 that can withstand the demands of various tool devices and applications.

As shown in FIGS. 2a, 2b, and 3 the housing 102, the battery pack 202, and the electrical connector 104 may be contained within a frame volume 208 bounded by the frame 106. The frame 106 may partially surround the exterior of the housing 102 such that the housing 102 does not touch the ground 206 when the frame 106 rests on the ground 206.

In one example, the frame 106 of the power unit 100 is designed to project beyond the housing 102 and the battery pack 202 when the battery pack 202 is mounted to the housing 102. This projection serves to protect the housing 102, the battery pack 202, and the electrical connector 104 from impact, such as during use or when the tool device is dropped. The frame 106 may be coupled to the housing 102 using housing connectors 204, which are connected between the frame 106 and the housing 102 in a plurality of positions. The housing connectors 204 provide secure attachment and fix the housing 102 with respect to the frame 106.

In some examples, the integration of the housing 102 with the frame 106 provides specific clearances between the housing 102, the frame 106, and the ground 206. These clearances serve to protect the housing 102, the battery pack 202, and the electrical connector 104 from impact and damage, as well as to provide optimal functionality for the tool device.

Various clearances may be provided between the housing 102, the frame 106, and the ground 206, including flexible tool connection frame clearance 210, forward sloped portion ground clearance 212, battery rear frame portion clearance 214, housing upper frame portion clearance 300, housing lower frame portion clearance 302, housing first frame side clearance 304, and housing second frame side clearance 306. As can be seen from FIGS. 2b and 3, each of the clearances 210, 212, 214, 300, 302,304, 306, is such that the housing 102 is positioned within the frame 106 such that the housing 102, the battery pack 202 or the electrical connector 104 do not project beyond the frame 106. These clearances serve to protect the housing 102, the battery pack 202, and the electrical connector 104 from impact and damage, as well as to provide optimal functionality for the tool device.

In some examples, the frame 102 comprises one or more fastening holes 134, 136 configured to receive a clip of a carry strap (not shown). As shown in FIGS. 1, 2a, 2b, 3 and 4, the first frame side 116 comprises a first fastening hole 134 and a second fastening hole 136. The first fastening hole 134 and the second fastening hole 136 are configured to receive a clip (e.g., a metal clip) of the carry strap. This means that the user can carry the power unit 100 over their shoulder when the carry strap is attached to the first fastening hole 134 and the second fastening hole 136. In some examples, the first fastening hole 134 and the second fastening hole 136 can each optionally comprise a metal insert. In this way, the strength and durability of the fastening holes is increased. Also, if the clip is made from metal, the clip of the carry strap does not wear the plastic material of the frame 102. The metal insert may be a hollow metal bushing (not shown) seated within the first fastening hole 134 and the second fastening hole 136. Whilst the first frame side 116 is shown having the first fastening hole 134 and the second fastening hole 136, in other examples the second frame side 118 can additionally or alternatively comprise the first fastening hole 134 and the second fastening hole 136.

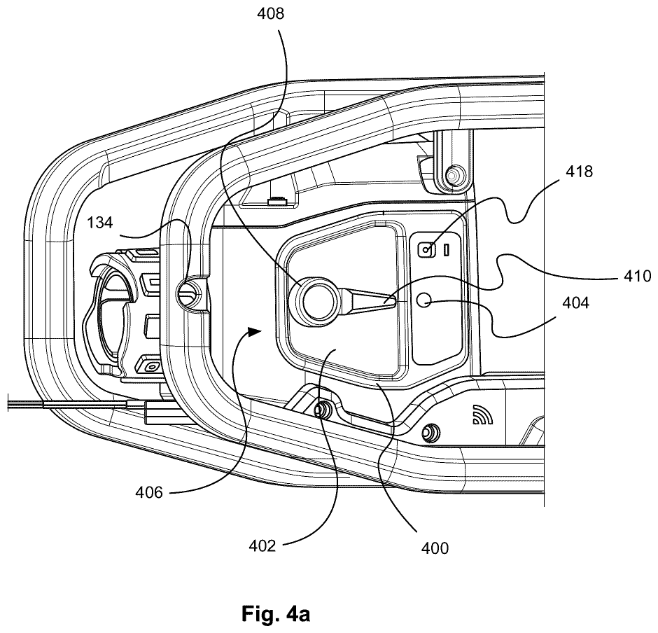

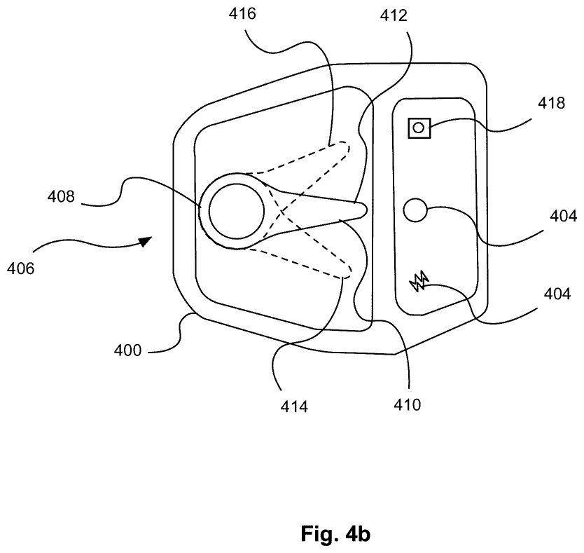

In some examples the power unit 100 comprises a rotary actuator 406 configured to change the operational mode of the power unit 100. The rotary actuator 406 will now be discussed further with respect to FIG. 4a.

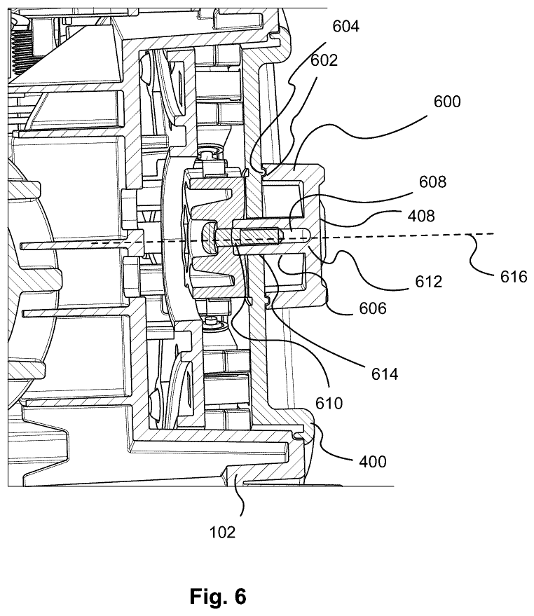

FIG. 4a shows the power unit 100 having a rotary actuator 406, which is rotatable about a rotary actuator rotation axis 616 (best shown in FIG. 6) between at least a first rotary actuator position 412 and a second rotary actuator position 414. The first rotary actuator position 412 corresponds to a power OFF mode (e.g. as shown in FIG. 4a), and the second rotary actuator position 414 corresponds to a first operational mode. FIG. 4a illustrates an example where the power unit 100 further comprises a remote device pairing button 418 configured to initiate pairing with the remote-control device.

In the example as shown in FIG. 4a, the electrical connector 104 is configured to electrically connect to the at least one electrical component with a flexible tool connection 130. The flexible tool connection 130 comprises at least one electrical wire configured to electrically connect the battery pack 202 and the at least one electrical component. The first operation mode corresponds to a power ON mode, and the second operational mode corresponds to a remote-control mode. The rotary actuator 406 includes a rotary actuator knob 408 mounted on a first end of a rotary actuator shaft 610.

In one example, the power unit 100 includes a rotary actuator 406 that is designed to provide a user-friendly interface for controlling the operational modes of the power unit 100. The rotary actuator 406 is rotatable about a rotary actuator rotation axis 616 and can be moved between at least a first rotary actuator position 412 and a second rotary actuator position 414. In some examples, the rotary actuator 406 may be further rotatable to a third rotary actuator position 416.

In some examples, the power unit 100 may comprise a rotary actuator plate 400 that includes a rotary actuator recess 402. The rotary actuator recess 402 is configured to receive the rotary actuator knob 408, providing a secure and stable connection between the rotary actuator 406 and the housing 102. This configuration ensures that the rotary actuator 406 remains in the selected position and prevents accidental changes in the operational mode.

The different positions for the rotary actuator 406 will now be discussed in more detail. FIG. 4b shows an example where the rotary actuator knob 408 comprises a tapered finger 410 configured to point to one or more rotary actuator position symbols 404, each corresponding respectively to the first, second or third rotary actuator position 412, 414, 416. FIG. 4b shows an example where the rotary actuator 406 is further rotatable to a third rotary actuator position 416. The third rotary actuator position 416 corresponds to the second operational mode.

In one example, the first rotary actuator position 412 corresponds to a power OFF mode, where the power unit 100 does not provide power to the tool device. This position allows the user to safely handle the tool device without the risk of accidental activation. The second rotary actuator position 414 corresponds to a first operational mode, such as a power ON mode, where the power unit 100 provides power to the tool device, enabling the user to operate the tool device as intended. In some examples, the power unit 100 may include a third rotary actuator position 416, which corresponds to a second operational mode, such as a wireless control operation mode. In this mode, the power unit 100 can be controlled remotely using a wireless remote-control module 728.

The distinct first, second and third rotary actuator positions 412, 414, 416 provide tactile feedback to the user, making it easy to select the desired operational mode, even when wearing gloves or in low visibility conditions.

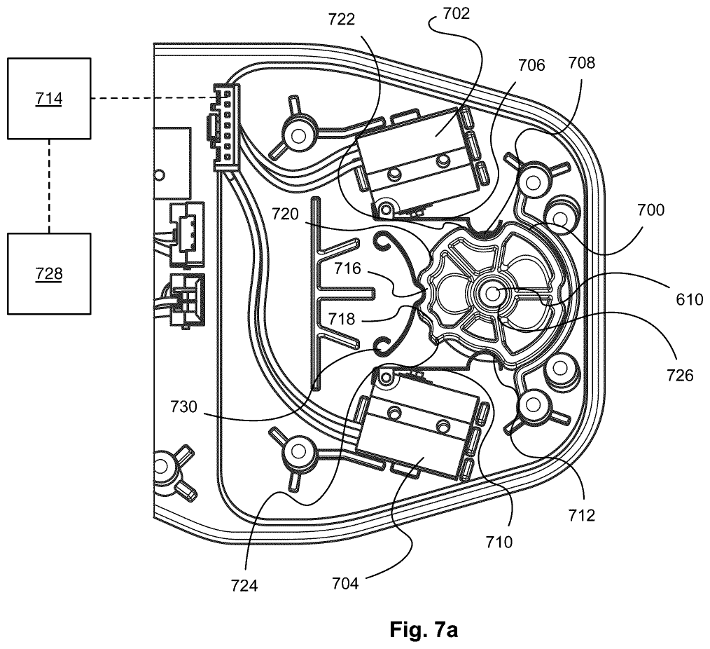

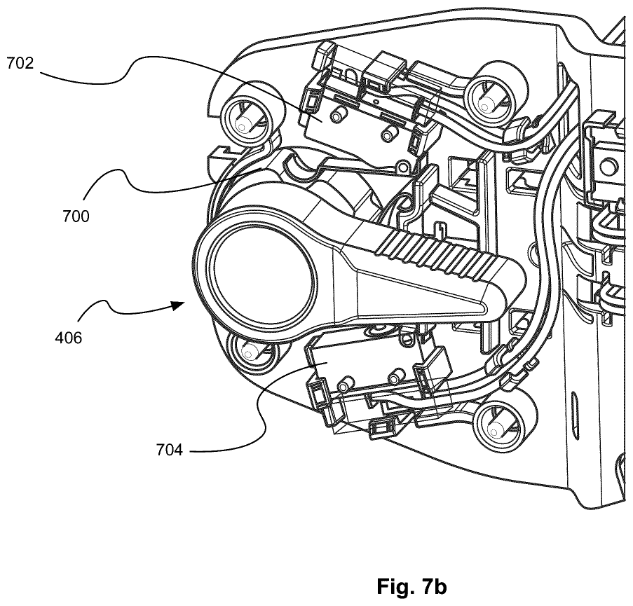

In one example, the rotary actuator 406 comprises a rotary actuator knob 408 mounted on a first end of a rotary actuator shaft 610 (best shown in FIGS. 6 and 7a). As mentioned above, the rotary actuator knob 408 has a tapered finger 410 that extends in a direction perpendicular to the rotary actuator rotation axis 616. The tapered finger 410 is configured to point to one or more rotary actuator position symbols 404 on a rotary actuator plate 400, each corresponding to one of the first, second or third rotary actuator position 412, 414, 416. The tapered finger 410 pointing to rotary actuator position symbols 404 is shown in FIG. 4b. This configuration allows the user to easily identify the current position of the rotary actuator 406 and select the desired operational mode.

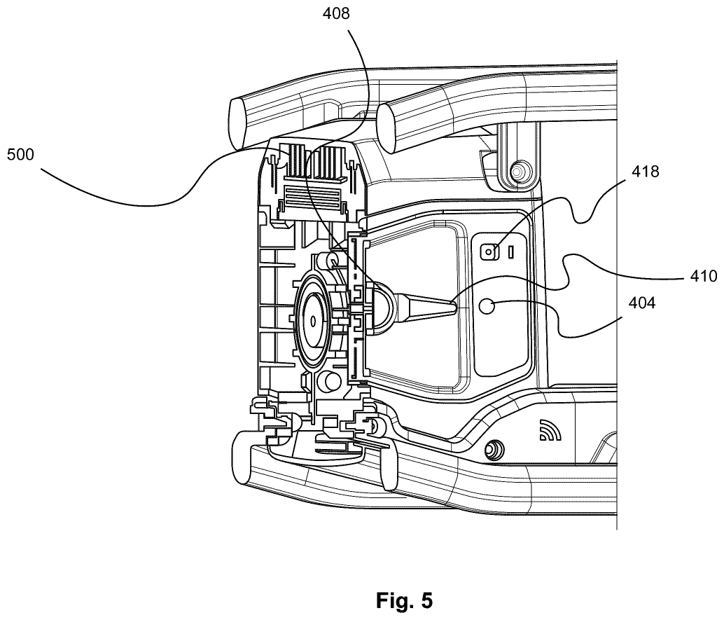

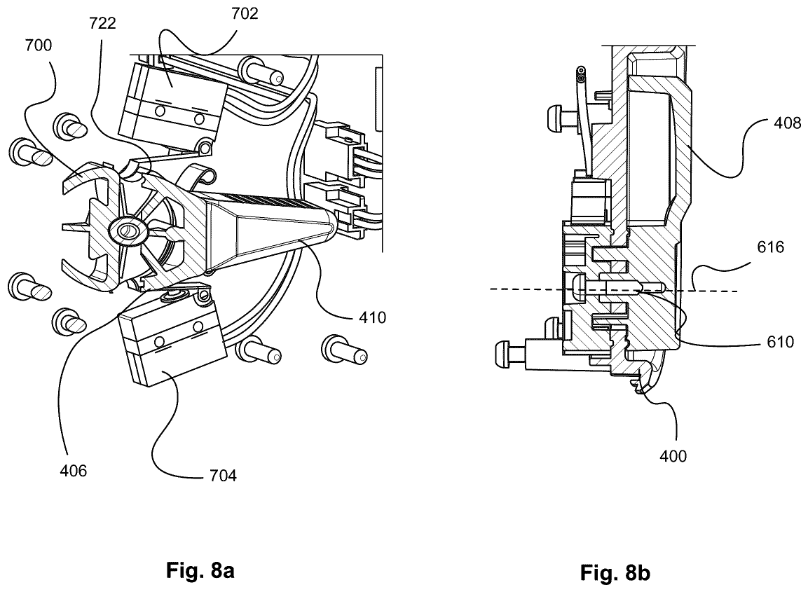

The function of the rotary actuator 406 will now be discussed in more detail with respect to FIGS. 5, 6, 7a, 7b, 8a and 8b.

In the example in FIG. 6, the housing 102 comprises an actuator through hole 614, and the rotary actuator 406 covers the actuator through hole 614 to protect internal components from debris and dust.

In one example, the power unit 100 is designed to provide effective protection for its internal components, ensuring that the power unit 100 remains functional and reliable even in challenging environments where debris and dust may be present.

In some examples, the housing 102 of the power unit 100 comprises an actuator through hole 614. The rotary actuator 406 is positioned to cover the actuator through hole 614, providing a barrier that helps protect the internal components of the power unit 100 from debris and dust. This arrangement ensures that the internal components remain clean and functional, reducing the risk of damage or malfunction due to the ingress of foreign particles.

In one example, the rotary actuator 406 is designed to provide an effective seal for the actuator through hole 614 in the housing 102. This seal helps to prevent the ingress of debris and dust into the power unit 100, ensuring that the internal components remain clean and functional. The rotary actuator 406 may comprise various features that contribute to the sealing and protection of the actuator through hole 614, as described in the following subsections.

In some examples, the rotary actuator knob 408 may comprise an actuator skirt 600 that abuts the housing 102. The actuator skirt 600 may include a skirt edge recess 602 that faces the rotary actuator plate 400. The housing 102 may comprise a reciprocal projecting element 604 configured to engage the skirt edge recess 602, thereby sealing the housing 102 and protecting the internal components from debris and dust. This engagement between the skirt edge recess 602 and the reciprocal projecting element 604 provides an effective seal for the actuator through hole 614, ensuring that the internal components of the power unit 100 remain clean and functional.

Optionally, an O-ring (not shown) may be provided between the skirt edge recess 602 and the rotary actuator plate 400 to further improve the sealing of the rotary actuator 406 and the housing 102.

As shown in FIG. 6, in one example, the rotary actuator 406 comprises a rotary actuator shaft 610 that is connected to the rotary actuator 406 and extends through the actuator through hole 614 in the housing 102. The rotary actuator shaft 610 is aligned with the rotary actuator rotation axis 616 and is configured to transmit mechanical movement from the rotary actuator 406 to the first and second microswitches 702, 704.

The rotary actuator knob 408 may further comprise a central actuator stem 606 that protrudes through the actuator through hole 614 in the housing 102 and into an inner ring recess 726 in the switch cam 700. The central actuator stem 606 provides an additional sealing mechanism for the actuator through hole 614, helping to protect the internal components of the power unit 100 from debris and dust.

The central actuator stem 606 may also comprise a central stem recess 608, into which the rotary actuator shaft 610 protrudes and is fixed to the central actuator stem 606. This arrangement further contributes to the sealing and protection of the actuator through hole 614, ensuring that the internal components of the power unit 100 remain clean and functional.

In the example shown in FIG. 7a, the controller 714 is further configured to provide power to the at least one electrical component of the tool device when the rotary actuator 406 is in the second rotary actuator position 414 or the third rotary actuator position 416.

The power unit 100 further comprises at least one microswitch 702, 704 configured to detect the rotary actuator 406 in the second rotary actuator position 414 or the third rotary actuator position 416 and generate a signal corresponding to the detected position.

FIG. 7a illustrates an example where the power unit 100 further comprises a controller 714 connected to the at least one microswitch 702, 704. The controller 714 is configured to detect the signal generated by the at least one microswitch and activate the corresponding operational mode of the power unit 100.

In the example shown in FIG. 7a, the rotary actuator 406 comprises a switch cam 700 mounted on the rotary actuator shaft 610 and configured to engage and actuate the at least one microswitch 702, 704 when the rotary actuator 406 is in the second rotary actuator position 414 or the third rotary actuator position 416. The engagement of the switch cam 700 with the microswitches 702, 704 allows for precise detection of the first, second or third rotary actuator positions 412, 414, 416 and activation of the corresponding operational modes.

In the example shown in FIG. 7a, the switch cam 700 comprises a first camming surface 722 configured to engage and move a first lever end 708 of a first microswitch 702 and actuate the first microswitch 702 when the rotary actuator 406 is in the second rotary actuator position 414.

The switch cam 700 also comprises a second camming surface 724 configured to engage and move a second lever end 712 of a second microswitch 704 and actuate the second microswitch 704 when the rotary actuator 406 is in the third rotary actuator position 416.

In one example, the switch cam 700 comprises a retaining spring element 730 and at least one retaining detent 716, 718, 720. As shown in FIG. 7a, the switch cam 700 comprises a first retaining detent 716, a second retaining detent 718 and a third retaining detent 720.

The retaining detents 716, 718, 720 are configured to positively retain the switch cam 700 and the rotary actuator 406. Specifically, the first retaining detent 716 is configured to retain the switch cam 700 and the rotary actuator 406 in the first rotary actuator position 412, second retaining detent 718 is configured to the retain the switch cam 700 and the rotary actuator 406 in the second rotary actuator position 414, and the third retaining detent 720 is configured to retain the switch cam 700 and the rotary actuator 406 in the third rotary actuator position 416. This feature provides additional stability and ensures that the rotary actuator 406 remains in the selected position during use.

The retaining spring element 730 provides tactile feedback to the user when the rotary actuator 406 is moved between positions, making it easy to identify the selected operational mode without the need for visual confirmation. The rotary actuator knob 408, tapered finger 410, and rotary actuator plate 400 provide a user friendly operating experience and prevents accidental changes in the operational mode. The retaining spring element 730 and retaining detents provide additional stability and tactile feedback, further enhancing the user experience.

In some examples, the switch cam 700 comprises an inner ring recess 726 that receives the central actuator stem 606. The inner ring recess 726 provides an additional sealing mechanism for the actuator through hole 614, helping to protect the internal components of the power unit 100 from debris and dust. This arrangement ensures that the internal components remain clean and functional, reducing the risk of damage or malfunction due to the ingress of foreign particles.

In one example and as shown in FIG. 7a, the power unit 100 comprises a first microswitch 702, and a second microswitch 704. The first and second microswitches 702, 704 are configured to detect the rotary actuator 406 in the second rotary actuator position 414 or the third rotary actuator position 416 and generate a signal corresponding to the detected position. The first and second microswitches 702, 704 provide a reliable and accurate means of detecting the position of the rotary actuator 406, ensuring that the power unit 100 operates in the correct mode based on the user's selection.

In one example, the first microswitch 702 may comprise a first switch lever 706 with a first lever end 708, which may be U-shaped. Similarly, the second microswitch 704 may comprise a second switch lever 710 with a second lever end 712, which may also be U-shaped. The first and second lever ends 708, 712 of the first microswitch 702 and the second microswitch 704 respectively provide a secure engagement with the first camming surface 722 and the second camming surface 724 switch cam 700.

Accordingly, when the rotary actuator 406 rotates from the first rotary actuator position 412 to the second rotary actuator position 414, the rotary actuator 406 moves from a 90-degree position/3 ‘o’clock position to a 120-degree position/4 ‘o’clock position. When this happens, the first camming surface 722 engages the first switch lever 706, moving the first switch lever 706 upwards and actuating the first microswitch 702.

Likewise, when the rotary actuator 406 rotates from the first rotary actuator position 412 to the third rotary actuator position 416, the rotary actuator 406 moves from a 90-degree position/3 ‘o’clock position to a 60-degree position/2 ‘o’clock position. When this happens, the second camming surface 724 engages the second switch lever 710, moving the second switch lever 710 upwards and actuating the second microswitch 704. This means that the rotary actuator 406 allows for accurate detection of the first, second or third rotary actuator positions 412, 414, 416 and reliable operation of the power unit 100.

As shown in FIG. 4b, optionally, the first rotary actuator position 412 is between the second rotary actuator position 414 and the third rotary actuator position 416. This means that the user moves the rotary actuator 406 in a clockwise direction from the first rotary actuator position 412 to the second rotary actuator position 414. In contrast the user moves the rotary actuator 406 in an anticlockwise direction from the first rotary actuator position 412 to the third rotary actuator position 416. This means it is harder for the user to accidentally select the first or second operational mode of the power unit 100 when turning the rotary actuator 406.

The first camming surface 722 and the second camming surface 724 are circumferentially offset from each other on the switch cam 700 such that only one or the other of the first and second camming surfaces 722, 724 is respectively actuating the first or second microswitch 702, 704.

In some additional examples, a fourth rotary actuator position (not shown) can be provided whereby a third and a fourth camming surfaces (not shown) respectively actuates the first microswitch 702 at the same time as the second microswitch 704. This means that a third operational mode of the power unit 100 can be selected without providing additional microswitches.

As discussed, the rotary actuator 406 provides a 30-degree angular separation between the first rotary actuator position 412 and the third rotary actuator position 416 and also between the first rotary actuator position 412 and the second rotary actuator position 414. However, in other examples there can be a larger angular separation between the first, second and third actuator positions 412, 414, 416. In some examples, the angular separation can be 45 degrees, 60 degrees, 75 degrees, 90 degrees, 100 degrees and 110 degrees. Indeed, the angular separation between adjacent rotary actuator positions 412, 414, 416 can be any suitable angle greater than 0 degrees and less than 120 degrees.

Whilst the examples discussed in reference to the Figures discuss two or three different positions for the rotary actuator 406, in other examples, there can be any suitable number of rotary actuator positions 412, 414, 416. For example, 4, 5, 6, etc different rotary actuator positions 412, 414, 416 each corresponding to a different operational mode of the power unit 100.

As discussed, in some examples, the microswitches 702, 704 are configured to detect the rotary actuator 406 in the second rotary actuator position 414 or the third rotary actuator position 416. The microswitches may be positioned such that they are engaged by the switch cam 700 when the rotary actuator 406 is in the second or third rotary actuator positions 414, 416. This engagement allows the microswitches to accurately detect the position of the rotary actuator 406 and generate a corresponding signal.

In some examples, the power unit 100 further comprises a controller 714 connected to the at least one microswitch 702, 704. The controller 714 is configured to detect the signal generated by the at least one microswitch and activate the corresponding operational mode of the power unit 100. In some examples, the first microswitch 702 is electrically connected to a first electrical circuit (not shown) and the second microswitch 704 is electrically connected to a second electrical circuit (not shown). The controller 714 is configured to detect a change in the condition (e.g., open or closed) of the first and second microswitches 702, 704 and determine the respective position of the rotary actuator 406. This ensures that the power unit 100 operates in the correct mode based on the user's selection, providing a seamless and intuitive user experience.

In some examples, the controller 714 is further configured to provide power to the at least one electrical component of the tool device when the rotary actuator 406 is in the second rotary actuator position 414 or the third rotary actuator position 416. This allows the power unit 100 to supply power to the tool device as needed, ensuring efficient and effective operation of the tool device.

Whilst the examples discussed herein use the first and second microswitch 702, 704 for detecting the position of the rotary actuator 406, any other suitable sensor can be used to detect the position of the rotary actuator 406 (E.g., an optical sensor or a Hall sensor etc.)

The second mode of operation of the power unit 100 will be discussed in more detail.

The power unit 100 further comprises a wireless remote-control module 728 configured to switch the power supply on and off remotely when the rotary actuator 406 is in the third rotary actuator position 416. The wireless remote-control module 728 is configured to communicate with a remote-control device using one or more of the following wireless protocols: Bluetooth, Zigbee, Wi-Fi, Infrared, RF (Radio Frequency), LoRa (Long Range), and/or Cellular network (e.g., 4G, 5G).

The wireless remote-control module 728 may be integrated within the housing 102 of the power unit 100 or may be a separate component that is electrically connected to the power unit 100.

In one example, the wireless remote-control module 728 allows the user to switch the power supply on and off remotely when the rotary actuator 406 is in the third rotary actuator position 416, which corresponds to a remote-control operational mode. This remote-control operational mode provides the user with increased flexibility and convenience in controlling the power supply to the tool device, particularly in situations where direct access to the power unit 100 may be difficult or unsafe.

In one example, the power unit 100 may further comprise a remote device pairing button 418 (best shown in FIGS. 4a, 4b and 5) configured to initiate the pairing process with the remote-control device. The remote device pairing button 418 may be located on the housing 102 of the power unit 100 and may be easily accessible to the user. When the user presses the remote device pairing button 418, the wireless remote-control module 728 may enter a pairing mode, during which it searches for compatible remote-control devices within its communication range.

The remote-control device may be any device capable of wirelessly communicating with the power unit 100 using one or more of the supported wireless protocols. Examples of remote-control devices include, but are not limited to, smartphone apps, handheld remote controls, wall-mounted remote controls, voice-activated remote controls, computer software, keychain remote controls, Wi-Fi-enabled remote controls, and gesture-based remote controls.

Once the wireless remote-control module 728 detects a compatible remote-control device, it may establish a secure connection with the device, allowing the user to remotely control the power supply to the tool device. The pairing process ensures that the power unit 100 can only be controlled by authorised remote control devices, providing increased security, and preventing unauthorised access to the power supply.

In some examples, the remote device pairing button 418 may only be functional when the rotary actuator 406 is in the third rotary actuator position 416.

In some examples, the power unit 100 may comprise additional features to enhance the functionality and usability of the wireless remote-control module 728. For example, the power unit 100 may comprise an LED indicator that provides visual feedback to the user regarding the connection status between the power unit 100 and the remote-control device. Additionally, the power unit 100 may comprise a memory module that stores information about previously paired remote-control devices, allowing for automatic reconnection when the power unit 100 and the remote-control device are within communication range.

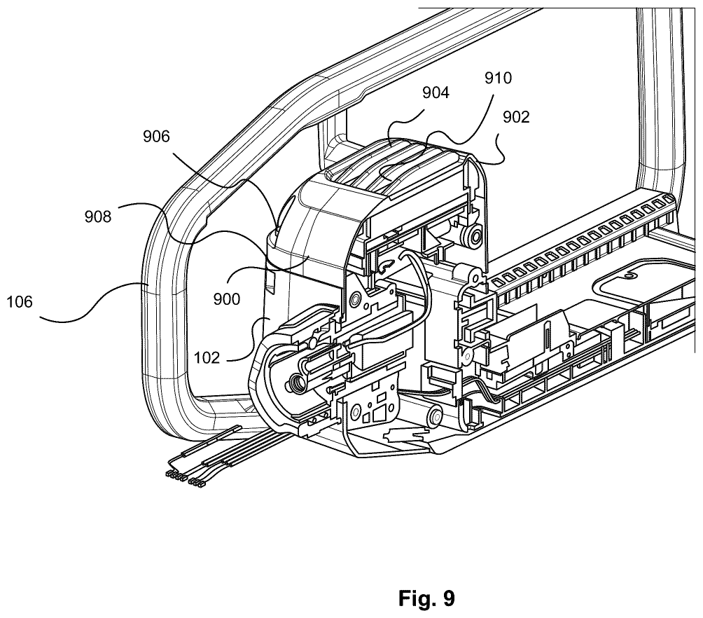

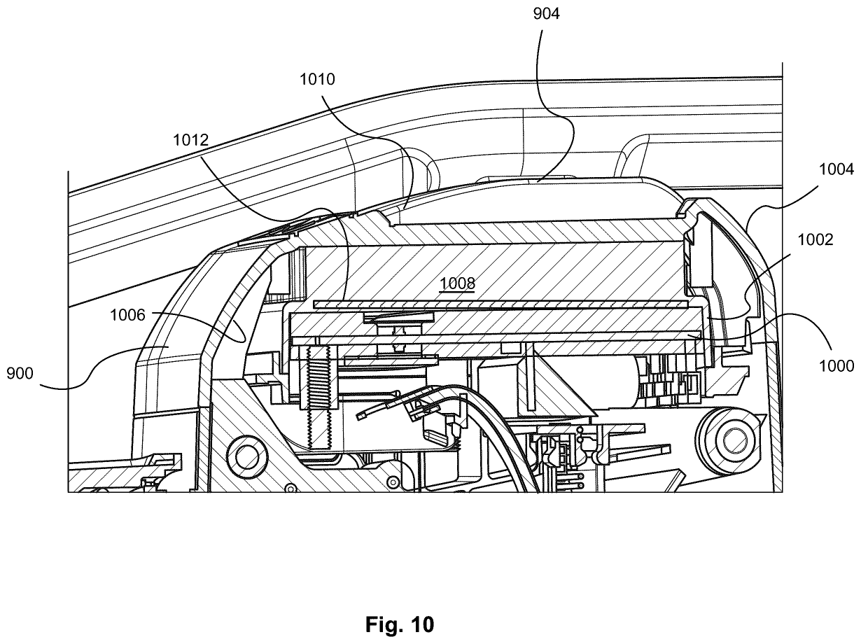

The power unit 100 comprises a housing 102 and a heat sink 900 in order to prevent the power unit 100 from overheating. The heat sink 900 will now be discussed in more detail with respect to FIGS. 9 and 10. The heat sink 900 functions as a top cover for the housing 102 and when the heat sink 900 is mounted on the housing 102, the heat sink 900 closes the housing 102 and substantially seals the housing 102 from moisture, dirt and debris. In some examples, as discussed below, the housing 102 may optionally be not fully sealed from the external environment.

FIG. 9 shows a power unit 100 for a tool comprising at least one electrical component. As discussed above, the power unit 100 is designed to provide power to a tool device comprising at least one electrical component. The power unit 100 includes various components that work together to ensure efficient power delivery, heat dissipation, and protection from external elements.

The structure of the heat sink 900 and function thereof play a role in the power unit 100, as it is responsible for dissipating heat generated by an electronics module 1000 during operation. In one example, the heat sink 900 is designed to effectively dissipate heat while maintaining a compact and robust structure that can withstand the harsh conditions of a worksite environment.

The electronics module 1000 is mounted within the housing 102, and the heat sink 900 is mounted to the housing 102 and coupled to the electronics module 1000. The heat sink 900 comprises an external surface 1004 forming part of the exterior of the housing 102. The electronics module 1000 is configured to manage the electrical power supplied by the battery pack 202 to the tool device electrical components (not shown). In some examples, the electronics module 1000 may include a controller 714 and a wireless remote-control module 728 for managing the power supply and communication with the tool. Thermal management of the electronics module 1000 allows for reliable operation and prevents overheating, which can lead to reduced performance or damage to the electronics.

In some examples, the heat sink 900 comprises a heat sink wall 902 that has an internal surface 1006 and an external surface 1004. The internal surface 1006 is in contact with the electronics module 1000 and is configured to transfer heat from the electronics module 1000 to the external surface 1004 of the heat sink 900. The external surface 1004 forms part of the exterior of the housing 102, which allows for improved heat dissipation to the outside environment. This integration with the exterior of the housing 102 provides a compact and efficient design that maximises heat transfer while minimising the overall size of the power unit 100. In some examples, the external surface 1004 of the heat sink 900 is flush with the surface of the housing 102 when mounted thereto.

In some examples, the heat sinks 900 optionally comprises external radiating ribs 904 projecting from the external surface 1004 of the heat sink 900. The external radiating ribs 904 are spaced at a distance of at least 6 mm from each other in some examples. In other examples, different spacing for the external radiating ribs 904 can be used. For example, the external radiating ribs 904 are separated by a distance of 5 mm, 7 mm, 8 mm, 9 mm, 10 mm, 11 mm, 12 mm, 13 mm, 14 mm, 15 mm, 16 mm, 17 mm, 18 mm, 19 mm, 20 mm. Indeed, any suitable spacing distance can be used between the external radiating ribs 904 such that the user can clean between the external radiating ribs 904. The user will often wish to keep the external radiating ribs 904 free from debris and dirt or e.g., wet concrete so that the external radiating ribs 904 can continue to radiate heat from the interior of the housing 102.

The heat sink 900 may also comprise external channels 910 defined by adjacent external radiating ribs 904. The external channels 910 further increase the surface area of the heat sink 900 and facilitate air flow around the external radiating ribs 904, which can help to improve heat dissipation.

The external radiating ribs 904 that project from the external surface 1004 of the heat sink 900 increase the surface area of the heat sink 900, which in turn improves heat dissipation. The external radiating ribs 904 may be spaced from each other at a suitable separation distance, allowing for easy cleaning of the space between ribs and preventing the build-up of dirt or debris that could hinder heat dissipation.

In some examples, the frame 106 projects outward from the housing 102 a greater distance than the external radiating ribs 904. This design feature provides protection for the external radiating ribs 904 from impact shock, which may occur during the operation of the tool or when the power unit 100 is subjected to rough handling or accidental drops. By extending further from the housing 102 than the external radiating ribs 904, the frame 106 helps prevent the user from touching the ribs, which may be hot during operation, and also reduces the likelihood of damage to the ribs due to impact or abrasion.

As mentioned above, the frame 106 may comprise a forward frame portion 110, which includes a first forward sloped portion 112 and a second forward sloped portion 114. These sloped portions provide additional structural support to the frame 106 and help distribute impact forces more evenly across the housing 102 and the heat sink 900, reducing the risk of damage to the power unit 100 and its components.

In some examples, the external radiating ribs 904 comprise rib end chamfers 1010. The rib end chamfers 1010 are designed to facilitate cleaning and reduce the build-up of debris, such as concrete, on the external radiating ribs 904. The incline of the rib end chamfers 1010 matches the incline of the first forward sloped portion 112 and the second forward sloped portion 114 of the frame 106.

The matching incline of the rib end chamfers 1010 and the first and second frame sloped portions 112, 114 allow for easier cleaning of the external radiating ribs 904, as a glove or cloth can be used to remove dirt or debris from between the ribs without getting caught on sharp edges or corners. This design feature also helps maintain the efficiency of the heat sink 900 by ensuring that the external radiating ribs 904 remain clean and free from debris, which could otherwise impede heat dissipation.

As shown in FIG. 10, in one example, the electronics module 1000 is housed within an internal heat sink volume 1008 defined by the heat sink wall 902. This positioning allows for efficient heat transfer from the electronics module 1000 to the heat sink 900, which then dissipates the heat to the external environment through the external surface 1004 and external radiating ribs 904. The internal heat sink volume 1008 may be designed to provide sufficient space for the electronics module 1000 and any additional components, such as a potting boat 1002 (discussed in more detail below), while maintaining effective heat transfer.

In some examples, the electronics module 1000 may be positioned adjacent to the internal surface 1006 of the heat sink wall 902 to facilitate direct heat transfer. This arrangement can improve the overall thermal conductivity and heat dissipation efficiency of the power unit 100.

In other examples which may be less preferred, the electronics module 1000 may be mounted in the interior of the housing 102, but not within the internal heat sink volume 1008.

The heat sink 900 may be made from various materials that have high thermal conductivity and are suitable for use in a tool environment. In some examples, the heat sink 900 may be made from one or more of aluminium, copper, steel, titanium, and/or graphite. Each of these materials has its own advantages in terms of thermal conductivity, weight, and cost, allowing for a range of options to suit different tool requirements and budgets.

The power unit 100 further optionally comprises a thermal paste 1012 applied between the electronics module 1000 and the heat sink 900. The thermal paste 1012 may comprise a thermally conductive compound that fills any gaps or irregularities between the electronics module 1000 and the heat sink 900, ensuring optimal contact and heat transfer between the two components.

The use of thermal paste 1012 can significantly enhance the overall thermal performance of the power unit 100 by reducing the thermal resistance between the electronics module 1000 and the heat sink 900. This can help maintain the electronics module 1000 at a lower temperature during operation, prolonging its lifespan and ensuring reliable performance.

In some examples, the power unit 100 may comprise a potting boat 1002 configured to receive the electronics module 1000. The potting boat 1002 can provide additional protection for the electronics module 1000 by encapsulating it in a thermally conductive material, such as a potting compound, which can further improve heat transfer between the electronics module 1000 and the heat sink 900.

The potting boat 1002 may be mounted within the internal heat sink volume 1008 adjacent to the internal surface 1006 of the heat sink wall 902. In some examples, the potting boat 1002 may be mounted directly to the heat sink 900 to ensure optimal heat transfer and thermal management.

The use of a potting boat 1002 can provide additional benefits, such as increased protection from external elements, improved mechanical stability, and enhanced heat dissipation. This can contribute to the overall reliability and performance of the power unit 100 in various operating conditions.

In some examples and shown in FIG. 5, the potting boat 1002 optionally comprises one or more potting boat radiating ribs 500. For the purposes of clarity, only one potting boat radiating rib 500 has been labelled in FIG. 5. The potting boat radiating ribs 500 extend through the internal heat sink volume 1008 and touch the internal surface 1006 of the heat sink wall 902. The potting boat radiating ribs 500 extend away from the electronics module 1000 towards the internal surface 1006. As shown in FIG. 5, the potting boat radiating ribs 500 extend and touch the internal surface 1006 of the heat sink wall 902 on a part of the heat sink 900 near the upper frame portion 124. In some examples, each potting boat radiating ribs 500 is aligned in the same plane as an external radiating rib 904. In some examples, the potting boat radiating ribs 500 are only internal to the housing 102 and have not contact with the outside airflow. This means that the potting boat radiating ribs 500 remain clean and free from dirt and debris.

The potting boat 1002 is optionally made from a thermally conductive material such as aluminium. The potting boat 1002 may be mounted to the heat sink 900 via a plastic fixing which secures the potting boat 1002 with respect to the housing 102 and the heat sink 900.

This means that the heat sink 900 comprises two cooling ribs structures. The first cooling structure are the external radiating ribs 904 and the second cooling structure is the potting boat radiating ribs 500.

In some examples, the heat sink 900 may be secured to the housing 102 using heat sink fasteners 906. The heat sink fasteners 906 may comprise various types of fastening mechanisms, such as screws, bolts, rivets, clamps, adhesive tape, or snap-fit connectors. The choice of fastener type may depend on factors such as ease of assembly, cost, and the specific requirements of the tool environment.

In some examples, the power unit 100 may comprise a housing 102 which is sealed to the heat sink 900. This means that the power unit 100 is designed to provide protection to the internal components, such as the electronics module 1000, from the external environment. However, in order to prevent condensation on the inside of the housing 102, one or more air holes in the housing 102 on the lower frame portion 126. The air holes are located in the housing 102 remote from the heat sink 900. In some examples, there optionally additionally or alternatively are no air holes in the housing 102 that are configured to provide a direct airflow over the electronics module 1000. For example, there are no airholes in the housing 102 located adjacent to the mounting position of the electronics module 1000 in the housing 102. This means that the electronics module 1000 can be better protected from the worksite environment. Also, in an embodiment, there is no fan in the housing 102 that can direct airflow over the electronics module 1000.

The junction between the housing 102 and the heat sink 900 may be still sealed. This may be achieved by using various sealing techniques and materials, such as gaskets, O-rings, or other sealing elements, to create a barrier between the internal components of the power unit 100 and the external environment. The housing 102 may be made from materials that are resistant to moisture, corrosion, and other environmental factors, such as plastics, metals, or composites. The housing 102 may also be designed to withstand various levels of pressure, temperature, and humidity, ensuring that the internal components of the power unit 100 remain protected and functional under different operating conditions.

In some examples, the power unit 100 may comprise a heat sink seal 908 mounted between the housing 102 and the heat sink 900. The heat sink seal 908 may be made from materials that are resistant to heat, moisture, and other environmental factors, such as silicone, rubber, or other elastomeric materials. The heat sink seal 908 may be designed to create a tight and secure seal between the housing 102 and the heat sink 900, preventing any external elements from entering the electronics module 1000 or the housing 102. As mentioned, one or more air holes may still be provided in the housing 102 on the lower frame portion 126 to avoid condensation inside the housing 102.

The heat sink seal 908 may be implemented using various techniques, such as adhesive bonding, mechanical fastening, or a combination of both. In some examples, the heat sink seal 908 may be integrated with the heat sink 900 or the housing 102, or it may be a separate component that is mounted between the heat sink 900 and the housing 102 during assembly.

The advantage of having a heat sink seal 908 is that it helps ensure a tight and secure seal between the housing 102 and the heat sink 900, preventing any external elements from entering near the electronics module 1000. In some examples the electronics module 1000 comprises a coating or a paste for insulating the mounted components and preventing short circuit.

In some examples, the heat sink 900 of the power unit 100 may optionally comprise at least one air flow channel (not shown) to facilitate ventilation and further improve heat dissipation. The air flow channels are designed to increase the surface area of the external surface 1004 of the heat sink 900 while maintaining the housing 102 sealed from the outside environment. In some examples the air flow channels (not shown) are positioned between the potting boat radiating ribs 500. Alternatively, the air flow channels are define by the potting boat radiating ribs 500 wherein at least part of a wall of the air flow channels are defined by one or more potting boat radiating ribs 500.

In one example, the air flow channels are not in fluid communication with the internal heat sink volume 1008. This means that the air flow channels do not allow air or other fluids to pass through and enter the internal heat sink volume 1008, thereby preventing ingress of water or dirt near the electronics module 1000. The air flow channels may be formed as through-holes in the heat sink 900, which allow air to flow through the heat sink 900 without entering the internal heat sink volume 1008.

The air flow channels may be strategically positioned and designed to maximise the surface area of the external surface 1004 of the heat sink 900, thereby improving heat dissipation and cooling efficiency. The increased surface area provided by the air flow channels allows for more efficient heat transfer from the heat sink 900 to the external environment, which in turn helps to maintain the temperature of the electronics module 1000 within an acceptable range during operation.

The air flow channels may be arranged in various patterns, such as parallel, radial, or spiral configurations, depending on the specific design requirements and constraints of the power unit 100 and the heat sink 900.

The size, shape, and orientation of the air flow channels may also be varied to optimise heat dissipation and cooling efficiency. For example, the air flow channels may have a circular, rectangular, or other cross-sectional shape, and may be oriented in a direction that is parallel, perpendicular, or oblique to the external surface 1004 of the heat sink 900. The dimensions of the air flow channels may be selected based on factors such as the desired cooling efficiency, the available space within the heat sink 900, and the manufacturing constraints of the heat sink 900.

In some examples, the power unit 100 may comprise additional features and enhancements related to the air flow channels and the ventilation of the heat sink 900. For example, the power unit 100 may include a fan or other active cooling mechanism to facilitate air flow through the air flow channels and enhance heat dissipation. Alternatively, the power unit 100 may incorporate passive cooling mechanisms, such as heat pipes or thermoelectric coolers, to further improve the cooling efficiency of the heat sink 900.

In addition to the features described above, the power unit 100 may comprise other optional components and design elements that further enhance the performance, durability, and user-friendliness of the power unit 100. For example, the power unit 100 may include additional sealing elements, fasteners, or mounting features to ensure a secure and reliable assembly of the various components within the housing 102. Furthermore, the power unit 100 may be designed to accommodate different types of battery packs 202, electrical connectors 104, and tool connections, providing greater versatility and compatibility with a wide range of tools and applications.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealised or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

1. A power unit for a tool comprising at least one electrical component, the power unit comprising:
a housing configured to removably receive at least one battery pack;
an electrical connector coupled to the housing and configured to electrically connect the at least one battery pack to at least one electrical component;
a frame coupled to the housing, wherein the frame projects beyond the housing and the electrical connector to protect the housing and the electrical connector from impact.

2. The power unit according to claim 1 wherein the electrical connector is configured to electrically connect to the at least one electrical component with a flexible tool connection comprising at least one electrical wire configured to electrically connect the battery pack and the at least one electrical component.

3. The power unit according to claim 1 wherein the frame projects beyond the housing and the battery pack when the battery pack is mounted to the housing to protect the battery pack from impact.

4. The power unit according to claim 1, wherein an outer part of the frame configured to engage the ground is symmetrical about a longitudinal axis of the power unit.

5. The power unit according to claim 1, wherein the frame comprises a forward frame portion having a forward sloped portion configured to provide a clearance between the forward frame portion and the ground.

6. The power unit according to claim 5, wherein the forward sloped portion is configured to allow sliding over rebars up to 35 mm in height difference.

7. The power unit according to claim 5, wherein the forward frame portion is smaller than a rear frame portion.

8. The power unit according to claim 5, wherein the forward sloped portion of the forward frame portion is configured to surround at least a portion of the electrical connector to provide protection to the electrical connector from impact or damage.

9. The power unit according to claim 1, wherein the frame is made from one or more of gas injection moulded plastic, injection moulded plastic, reinforced plastic, composite material, fibreglass, and/or carbon fibre.

10. The power unit according to claim 1, wherein the frame further comprises one or more fastening holes configured to engage with a carry strap clip.

11. The power unit according to claim 1, wherein the frame further comprises one or more metal inserts arranged to increase the stiffness of the frame.

12. The power unit according to claim 1, wherein the frame comprises a first frame side and a second frame side, and at least one cross strut connected between the first frame side and the second frame side.

13. The power unit according to claim 1, wherein the housing, the battery pack, and the electrical connector are contained within a volume bounded by the frame.

14. The power unit according to claim 1, wherein the frame comprises a first ground contacting rail and a second ground contacting rail that are parallel to the ground when contacting the ground.

15. The power unit according to claim 1, wherein the frame partially surrounds the exterior of the housing such that the housing does not touch the ground when the frame rests on the ground.

16. The power unit according to claim 1, wherein the at least one electrical component comprises one or more of a motor, switch, circuit board, LED indicator, heating element, sensor, solenoid, transformer, capacitor, resistor, transistor, fuse, relay, microcontroller, power supply, potentiometer, and encoder.
